(19) United States
(12) Patent Application Publication
(10) Pub. No.: US 2023/0231030 A1
(43) Pub. Date: Jul. 20, 2023

(54) NEURONS AND SYNAPSES WITH FERROELECTRICALLY MODULATED METAL-SEMICONDUCTOR SCHOTTKY DIODES AND METHOD

(71) Applicant: Forschungszentrum Jülich GmbH, Jülich (DE)

(72) Inventor: Qing-Tai ZHAO, Jülich (DE)

(21) Appl. No.: 18/007,721

(22) PCT Filed: Jun. 8, 2021
(86) PCT No.: PCT/EP2021/065297

§ 371 Date: Dec. 1, 2022

(30) Foreign Application Priority Data
Jun. 16, 2020 (DE) 10 2020 207 439.9

(51) Int. Cl. H01L 29/51; H10B 51/30; G11C 11/22; G11C 11/54; H01L 29/872; H01L 29/78

(52) U.S. Cl. CPC H01L 29/516; G11C 11/54; G11C 11/223; H01L 29/872; H01L 29/78391; H10B 51/30; G06N 3/063

(57) ABSTRACT

This disclosure relates to a synaptic component for a neural network having a layer of a semiconductor and a source electrode connected to the semiconducting layer and a drain electrode connected to the semiconducting layer, wherein the source electrode is spatially separated from the drain electrode, wherein the source electrode and the semiconducting layer form a Schottky diode, wherein the source electrode is separated from a first gate electrode by ferroelectric material. This disclosure further relates to a method for operating a synaptic component according to the disclosure in which the first Schottky diode is connected in reverse direction and an electric voltage is applied on the first gate electrode in a pulsed manner.

The invention relates to a synaptic component for a neural network. By synaptic component is meant an electronic component having properties of a biological synapse. In the following, the electronic component is therefore also referred to as a synapse. By neural network is meant an artificial neural network.

A brain is a biological neural network. It comprises a plurality of biological neurons, i.e. nerve cells. A biological neuron can transmit information to another biological neuron via biological synapses. This is done by means of an output channel of the biological neuron. Such an output channel is called an axon. The other biological neuron has an input channel. The input channel is called a dendrite. Through the input channel, the other biological neuron can receive the information. The decision of whether a biological neuron triggers an action potential through its axon and thus transmits information depends on the totality of incoming signals. The influence of one biological neuron on another biological neuron om biological synapses can change over time with the activity of the biological synapses. Such influence is called “synaptic weight” of a biological neuron.

The properties and behaviors of a neural network should be similar to the properties and behaviors of a biological neural network. A neural network shall be able to recognize patterns by means of adaptive algorithms. A neural network shall, comparable to the human brain, not have to start from scratch for every task or problem. It should have the possibility to draw on already acquired knowledge and already made experiences.

A neural network with memristors is known from the publication CN 208922326 U. Scaling, stability and blocking capability are problematic for a neural network with memristors.

The publication WO 2019147859 A2 discloses an electronic component having a semiconductor channel. An input electrode is adjacent to one end of the semiconductor channel. An output electrode is adjacent to the other end of the semiconductor channel. Above the semiconductor channel, there is a layer of dielectric material. A circuit of semiconductor materials serving as a synapse with an electrically charged carrier gas is described in the publication EP 0 529 565 B1. An integrated circuit for providing a synapse is known from the publication US 2019164597 A1.

If a neural network is to be realized with conventional CMOS technology, a plurality of transistors is required. Manufacturing effort and energy consumption are then high. A neural network can comprise ferroelectric field effect transistors (FeFET). Traditional ferroelectric materials such as lead zirconate titanate (PZT) are harmful to the environment and incompatible with established CMOS technology.

It is the task of the invention to provide a synapse, i.e., a synaptic component with improved properties.

A synaptic component (synaptic device) having the features of claim 1 serves to solve the task. The dependent claims relate to advantageous embodiments of the invention. The additional claim relates to a method for operating the synaptic component.

Claim 1 relates to a synaptic component for a neural network. The synaptic component comprises a layer consisting of a semiconductor. The layer consisting of a semiconductor is called a semiconducting layer. A source electrode is connected to the semiconducting layer. A drain electrode is connected to the semiconducting layer. The source electrode is spatially separated from the drain electrode. The source electrode and the semiconducting layer form a Schottky diode. The source electrode is separated from a first gate electrode by ferroelectric material. The drain electrode may be separated from a second gate electrode by ferroelectric material. The two gate electrodes are spatially separated from each other.

An electrode is separated from another electrode if there is a distance between the two electrodes. Spatially separated electrodes therefore do not contact each other. There is therefore no electrically conductive connection between the two electrodes. By means of the ferroelectric material, an electrical voltage applied to the first gate electrode can be transferred to the source electrode. The same applies in the case that a second gate electrode is separated from the drain electrode by ferroelectric material. Usually, one gate electrode is located on one side of the ferroelectric material and the other source and/or drain electrode is located on an opposite side of the ferroelectric material. The two electrodes may be directly connected to the ferroelectric material. The invention exploits the memory properties of ferroelectric material to imitate the behavior of a biological synapse.

A Schottky diode may comprise a metal layer applied on a semiconducting layer such as a silicon layer. A metal layer is a layer that consists of metal. A silicon layer is a layer that consists of silicon. Silicon is a semiconductor, i.e. a chemical substance whose electrical conductivity is between that of electrical conductors and that of electrical insulators.

The silicon layer can be, for example, n silicon, i.e. an n-type doped silicon layer. Electrons from the n-conductive silicon layer migrate to the metal layer. Because electrons move more easily from n-conductive silicon to the metal layer than vice versa, a region depleted of electrons is formed in the silicon layer. This region is called a Schottky barrier. Thus, a barrier layer and/or space charge zone is created. In addition, an electric field is created. The electric field counteracts the migration of the electrodes. If the electric field is large enough, electrons no longer migrate from the n-conductive silicon layer to the metal layer. However, the silicon layer can also be p silicon, i.e. a p-type doped silicon layer.

If a positive electrical voltage is applied to n-conductive silicon and a negative electrical voltage is applied to the metal layer, the space charge zone becomes larger. The Schottky diode is then connected in reverse direction.

If an electrically negative voltage is applied to n-conductive silicon and an electrically positive voltage is applied to the metal layer, then the Schottky diode is connected in the forward direction. Electrons flow from n silicon into the metal layer. If the Schottky diode is connected in forward direction, then the space charge zone is cleared.

An electrode is an electrical conductor. An electrode generally consists of metal.

A layer according to the invention may run in a straight line, i.e. along a plane. However, a layer according to the invention can also be round and/or angular.

With the component having the features of claim 1, the behavior of a biological synapse can be imitated. The component can be manufactured with low technical effort. The component can be manufactured from environmentally friendly materials.

The source electrode and the drain electrode may be on one side of the semiconducting layer. Such a component can be produced in a technically simple manner. The source electrode and the drain electrode can be produced on a surface of the semiconducting layer by deposition.

The source electrode and the drain electrode may be at opposite ends of the semiconducting layer. In this way, a suitable distance can be provided between the source electrode and the drain electrode.

To produce the component in a technically simple manner, the component may comprise a substrate. The semiconducting layer is then applied above the substrate. The semiconducting layer may be a thin layer. The substrate may consist of silicon. There may be an electrically insulating layer between the substrate and the semiconductor. Interfering influences may be prevented by the electrically insulating layer.

Ferroelectric material of the component may be in the form of a layer. A layer of ferroelectric material may therefore be applied on the source electrode. A layer of ferroelectric material may therefore be applied on the drain electrode. A ferroelectric layer may be partially located on the semiconducting layer to enable technically simple production. A ferroelectric layer may be partially located on the source electrode and/or drain electrode. There need not necessarily be two spatially separated layers of ferroelectric material. It can be a single layer of ferroelectric material, which is at least partially on the source electrode and at least partially on the drain electrode. This can also facilitate producing.

A first and/or second gate electrode may be applied on the opposite side of such a ferroelectric layer. The first gate electrode and/or the second gate electrode are located on one side of the ferroelectric layer. The source electrode and/or the drain electrode are located on the opposite side of the ferroelectric layer.

A drain electrode consisting of metal may serve as substrate of the synaptic component. Semiconductor material may first be applied on the substrate. Above the semiconductor material, the metal for a source electrode may be applied. Ferroelectric material may be applied on the source electrode. Metal for a gate electrode may be applied on the ferroelectric material. A vertical construction is thus possible.

One or more electrically insulating layers may be provided during producing to produce a synaptic component in a technically simple manner. For example, an insulating layer with recesses may be applied on a semiconducting layer. The semiconducting layer may be contacted through the recesses. The recesses may be at least partially coated with metal to produce Schottky diodes, for example. The insulating layer with the recesses helps to keep the two electrodes electrically separated. Producing one or more insulating layers may also be advantageous in a vertical construction. The electrically insulating layer may cover the semi-material, as far as the semiconducting material is not to be contacted by metallic electrodes.

A plurality of synaptic components can be produced in a simple manner, which are electrically connected in parallel and/or in series. A so-called crossbar structure can be produced, which can be advantageous in neural networks.

The semiconductor material may be selected from: Si, Ge, SiGe, SiGeSn, GeSn, SiC. The semiconductor material may be a III-V compound semiconductor, II-VI compound semiconductor. The semiconductor material may be a 2D material, which thus consists of only one layer or only a few layers of atoms and molecules. The semiconductor material may be a substrate or a semiconductor layer on a substrate, such as a “silicon-on-insulator” (SOI). By substrate is meant a self-supporting layer, which can therefore serve as a carrier for other layers. For producing the component, it can therefore be assumed that there is a substrate on which further layers can be deposited. The semiconductor material may be a semiconductor heterostructure with several semiconductor layers.

The ferroelectric material may be selected from: HfO₂-based ferroelectric, perovskite ferroelectric, and organic ferroelectric. The ferroelectric material, such as HfO₂-based ferroelectric, may be doped. Doping may have occurred with one or more of the following elements: N, Al, Si, Sc, Ge, Y, Zr, Gd, Pr, Sr, Tb, La, Lu.

The metal for the Schottky diode may be selected from: Al, Ag, Au, Cu, Cr, Mo, Ni, Nb, Pt, Ti, Ni, TiN, TaN, and metal alloys. The metal for the Schottky diode may be a metal semiconductor alloy such as silicides, germanides, metal-SiGeSn alloys.

Through the invention, artificial synaptic elements based on metal/semiconductor Schottky barriers may be provided. The polarization of the ferroelectric layers leads to a shielding charge at the metal/semiconductor interface, so that the effective strength of the Schottky barrier in the metal/semiconductor contact is modulated. The polarization switching in multidomain systems induces multi-level charge distributions at the metal/semiconductor interface, causing a multilevel conduction of the diode. This can be exploited to imitate properties of synapses.

The present invention solves the problem of interface traps at the interface between ferroelectric and semiconducting material in FeFETs, because the ferroelectric material is primarily disposed on the metal. The ferroelectric devices according to the invention can be produced at relatively low temperatures (<800° C.) using the CMOS process. As a result, almost all ferroelectric materials can be used.

The invention provides a method of constructing artificial synapses, which may be produced according to the following pattern. They may comprise two metal/semiconductor Schottky diodes which are connected at the back and contacted with a ferroelectric layer and a gate electrode. The thickness of the ferroelectric layer on the two Schottky diodes may be identical or different. This also applies to the choice of material for the ferroelectric layer. One Schottky diode can act as a signal input, while the second Schottky diode can be used to control the synaptic weight. By applying a constant bias voltage to the second Schottky diode, the synaptic weight can also be adjusted via the control voltage on the first Schottky diode. Instead of a second Schottky diode, a metal-semiconductor junction may be present, which acts like an ohmic contact.

Additional effects occur with artificial synapses with reversed bias voltage of the metal/semiconductor Schottky diode, which are covered with a ferroelectric layer. Here the drain electrode can be realized by an ohmic contact at the semiconductor.

The invention also relates to a method for operating a synaptic component according to the invention. The first Schottky diode is connected in reverse direction (reverse biased) during operation. An electrical voltage is applied to the first gate electrode in a pulsed manner. The synaptic component then behaves like a biological synapse.

The figures show

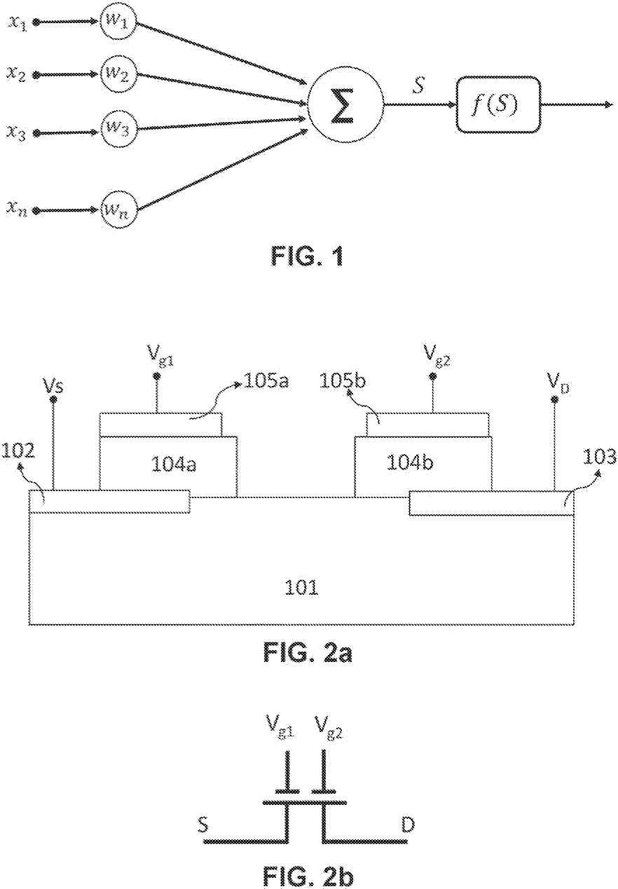

FIG. 1: Functional principle of a neural gate;

FIG. 2a: Configuration of a synapse;

FIG. 2b: Symbol representation of the synapse according to FIG. 2a;

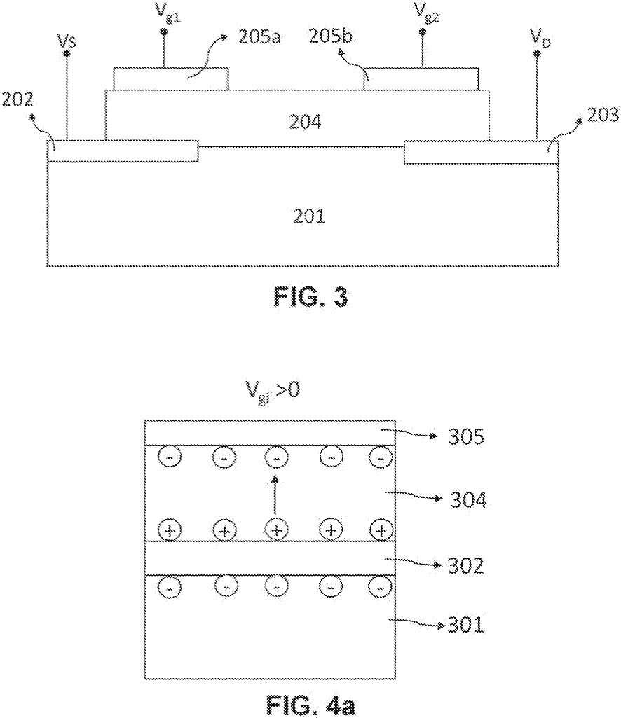

FIG. 3: Configuration of a synapse;

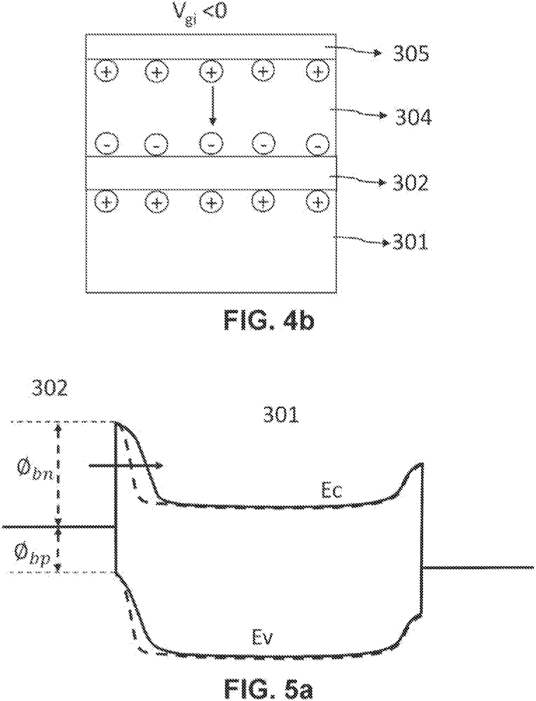

FIG. 4a: Modulation of a Schottky diode by a positive gate voltage;

FIG. 4b: Modulation of a Schottky diode by a negative gate voltage;

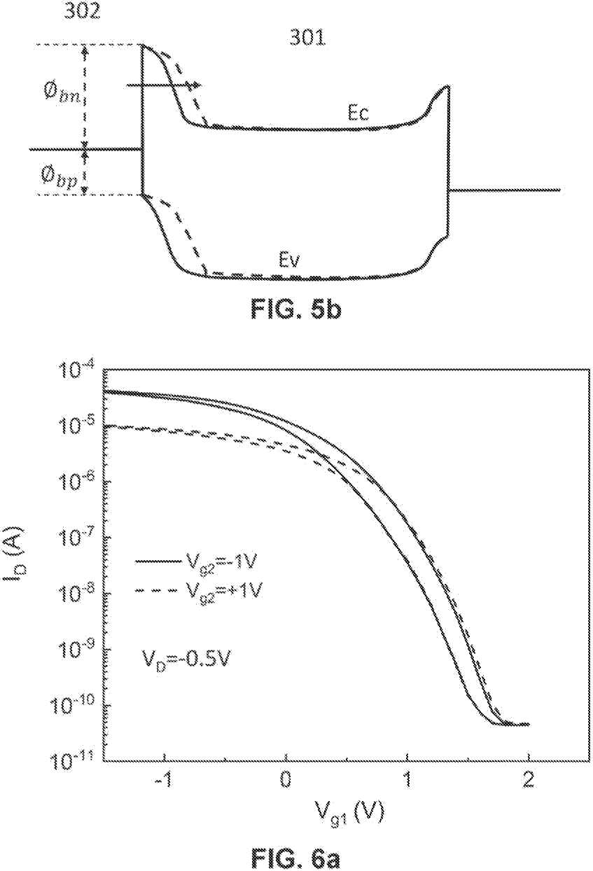

FIG. 5a: Band model of a Schottky diode with positive gate voltage;

FIG. 5b: Band model of a Schottky diode with negative gate voltage;

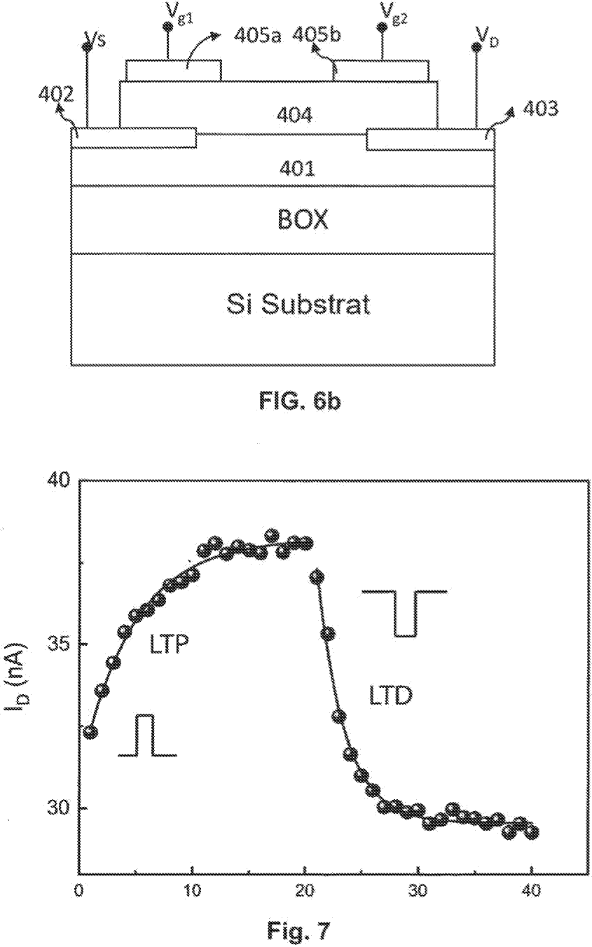

FIG. 6a: Current-voltage curve;

FIG. 6b: Configuration of a synapse;

FIG. 7: Pulse-current graph;

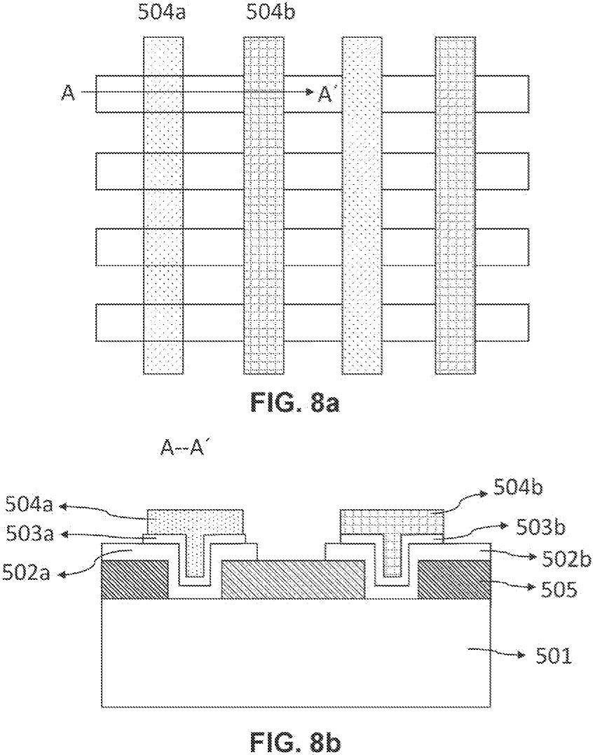

FIG. 8a: Configuration for a plurality of synapses

FIG. 8b: Sectional view of FIG. 8a;

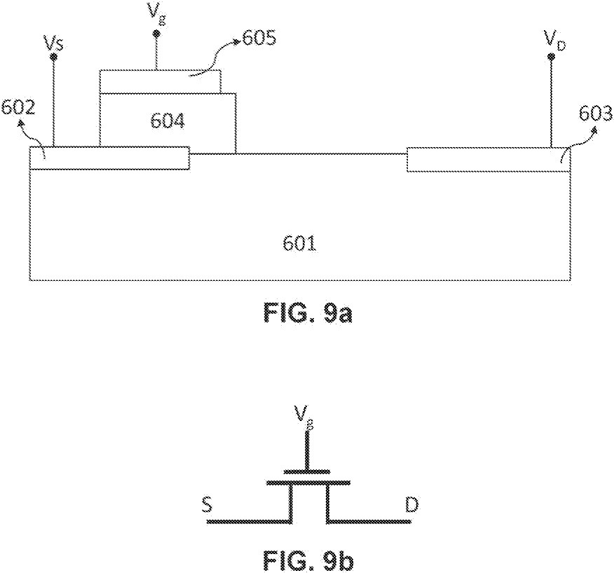

FIG. 9a: Configuration of a synapse;

FIG. 9b: Symbol representation of the synapse from FIG. 9a;

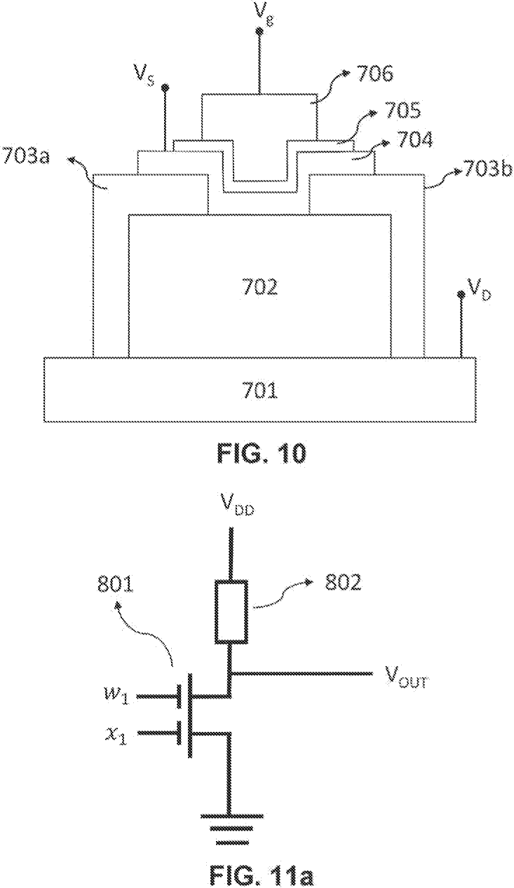

FIG. 10: Vertical arrangement of a synaptic element;

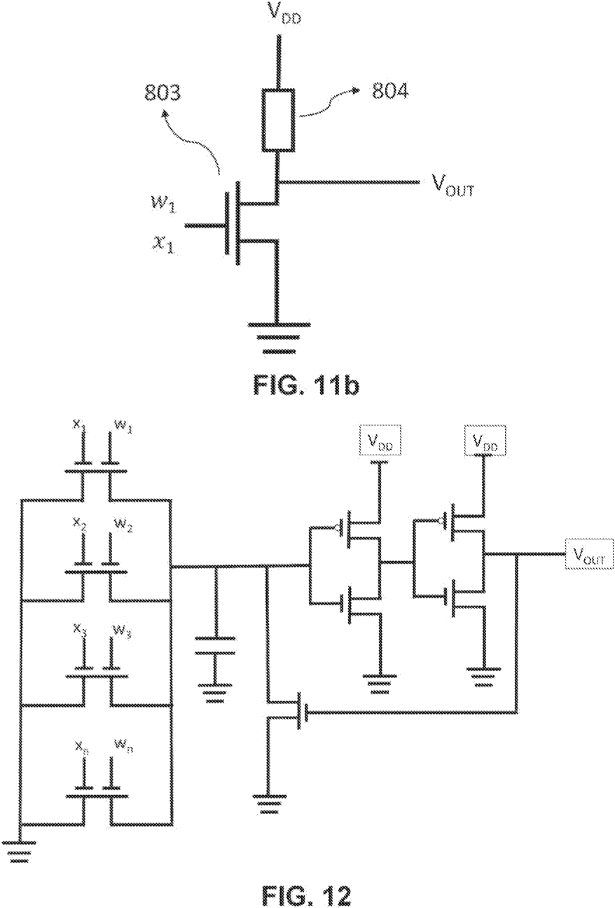

FIGS. 11a, b: Symbol representations of a neural element;

FIG. 12: Neural network;

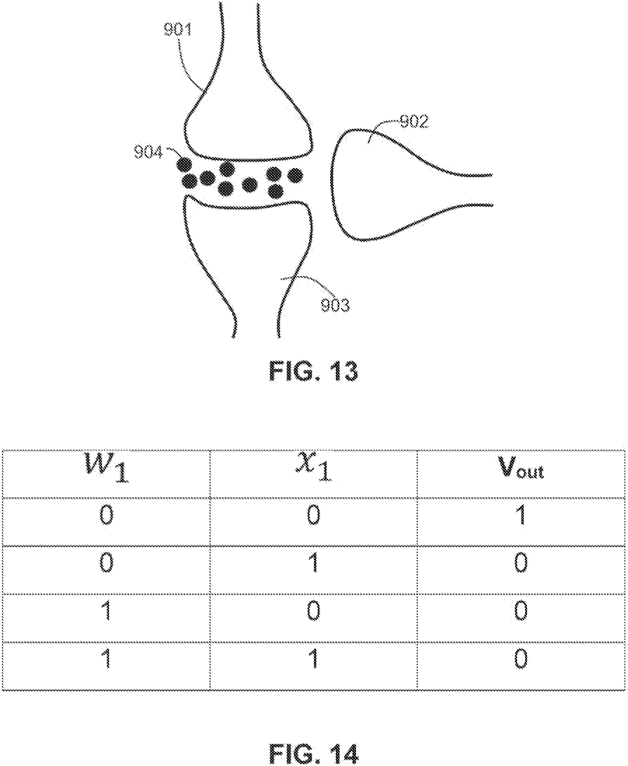

FIG. 13: Real representation of a synapse;

FIG. 14: NAND gate;

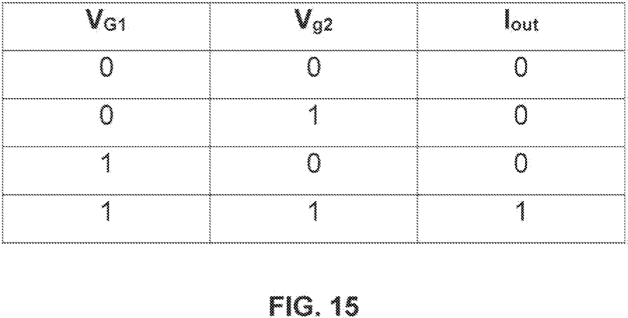

FIG. 15: AND gate.

FIG. 1 shows the operating principle of a neural gate, which consists of several input synapses xi to xₙ and a neuron. The input signals of the synapses xᵢ with the weights wᵢ are integrated with the following function:

$$\text{S} = {\sum }_{i = 1}^{n} {x}_{i} {w}_{i} + θ$$

S here is the integration over the input signals with the associated weights and 0 is an offset. The neural function ƒ(s) acts as a threshold function. Once S reaches a threshold value, the neuron with the function ƒ(s) is activated.

FIG. 2 shows a first configuration of a synapse. The synapse comprises a layer 101 consisting of a semiconductor. On the semiconducting layer 101, there are a source electrode 102 and a drain electrode 103. The two electrodes 102, 103 are spatially separated from each other. The two electrodes 102, 103 may be present adjacent to the end faces of the semiconducting layer 101. The two electrodes 102, 103 consist of metal. The two electrodes 102, 103 may be in the form of layers. An electric potential Vs may be applied to the source electrode 102. An electric potential V_{D} may be applied to the drain electrode 103. The electric potential Vs is different from the electric potential V_{D}.

The metal of the source electrode 102 and the semiconductor material of the semiconducting layer 101 are selected such that the junction between the source electrode 102 and the semiconducting layer 101 is a Schottky contact. Thus, there is a first Schottky diode formed by the source electrode 102 and the semiconducting layer 101.

The metal of the drain electrode 103 and the semiconductor material of the semiconducting layer 101 may be selected such that the junction between the drain electrode 103 and the semiconducting layer 101 is a Schottky contact. Thus, the drain electrode 103 and the semiconducting layer 101 may form a second Schottky diode.

In an equivalent circuit, the first Schottky diode and the second Schottky diode are connected “back-to-back”. A potential difference between the electrical potential Vs and the electrical potential V_{D} therefore results in one Schottky diode being connected in the reverse direction and the other Schottky diode being connected in the forward direction.

An electric current can flow from the source electrode 102 to the drain electrode 103 due to the potential difference between the electric potential Vs and the electric potential V_{D}. When an electric current flows from the source electrode 102 to the drain electrode 103, the electric current passes the first Schottky diode in the reverse direction and the second Schottky diode in the forward direction. Flowing of the electric current in reverse direction can be done by electrons tunneling through the junction of the first Schottky diode. If the electric current flows through the second Schottky diode in the forward direction, the second Schottky diode acts like an ohmic resistor.

Above the source electrode 102 there is a first ferroelectric layer 104a. The first ferroelectric layer 104a may cover a part of the source electrode 102. The first ferroelectric layer 104a overlaps with the semiconducting layer 101.

Above the drain electrode 103A there is a second ferroelectric layer 104b. The second ferroelectric layer 104b covers a part of the source electrode 103. The second ferroelectric layer 104b overlaps with the semiconducting layer 101.

A first electrode 105a is located on the first ferroelectric layer 104a. A second electrode 105b is located on the second ferroelectric layer 104b. Both electrodes 105a and 105b may consist of metal.

The synapse is configured such that an electric potential V_{g1} can be applied to the first electrode 105a. The Schottky barrier of the first Schottky diode may be modulated by an applied electrical potential V_{g1}. The synapse is configured such that an electrical potential V_{g2} can be applied to the second electrode 105a. The Schottky barrier of the second Schottky diode may be modulated by an applied electrical potential V_{g2}.

The first electric potential V_{g1} can be understood as a synaptic input signal within a neural network. The second electrical potential V_{g2} may be used to control weights within a neural network.

The ferroelectric layers 104a and/or 104b may overlap regions of the electrodes 102 and 103, applied on the semiconducting layer 101. Production may thus be facilitated. Also, the Schottky barriers of the first and second Schottky diodes can be modulated in a more controlled manner.

FIG. 2b shows an electrical symbol of the synapse shown in FIG. 2a with the source electrode S and the drain electrode D.

In FIG. 3, a second configuration of a synapse is shown that has only one continuous ferroelectric layer 204 instead of two ferroelectric layers 204a and 204b. In addition, the synapse shown here has a layer 201 that consists of a semiconductor. On the semiconducting layer 201, as in the case of FIG. 2a, there are a source electrode 202 and a drain electrode 203. The metal of the source electrode 202 and the semiconductor material of the semiconducting layer 201 are selected such that the junction between the source electrode 202 and the semiconducting layer 201 is a Schottky contact. The metal of the drain electrode 203 and the semiconductor material of the semiconducting layer 201 may be selected such that the junction between the drain electrode 203 and the semiconducting layer 201 is a Schottky contact. A first electrode 205a and a second electrode 205b are located on the ferroelectric layer 204. The electrical symbol of FIG. 2b may also represent the synapse shown in FIG. 3.

FIGS. 4a and 4b illustrate the modulation of the Schottky barriers by applying an electric potential V_{gi}, wherein V_{gi} with i = 1 or i =2. FIG. 4a illustrates the case where a voltage and/or electric potential applied to electrode 305 is positive. The polarization of the ferroelectric causes non-volatile memory effects so that electrons are present in the semiconductor layer 301. FIG. 4b illustrates the situation when a negative voltage V_{gi} is applied to the first and/or second electrodes 305, respectively, wherein positive charges (holes) are present in the semiconductor layer 301 due to polarization-induced non-volatile memory effects. Consequently, the thickness of a Schottky barrier can be modulated by applying potentials V_{gi}. This affects the flow of electrical tunnel currents.

FIG. 5 illustrates, using the band model, a modulation of a Schottky barrier from the metal layer 302 shown in the figure to the n-type doped semiconducting layer 301. When a positive voltage V_{gi} is applied, as shown in FIG. 4a, more electrons are generated at the metal-semiconductor interface. The band curvature (dashed line) is enhanced. A smaller Schottky barrier results. This causes a higher tunnel current density along the arrow, which can be formulated as follows:

$${J}_{t} \sim exp \left(- \frac{q {∅}_{b n}}{\sqrt{{N}_{D}}}\right)$$

Here ∅_{bn} is the height of the Schottky barrier for the electrons. q is the charge of the electrons. N_{D} is the doping concentration at the surface of the semiconductor 301.

If the voltage V_{gi} shown in FIG. 4b is negative, the depletion causes a smaller N_{D} and thus a wider Schottky barrier. A smaller current density along the arrow is the result. Thus, by modulating the multidomain polarization of the ferroelectric, the doping concentration in the metal-semiconductor interface can be regulated and hence the conductivity of the Schottky diode.

For a p-type doped semiconductor, the polarization and bias points in the opposite direction. The Schottky barrier is ∅_{bp}·

FIG. 6a presents an example of a measurement of an electric current I_{D} as a function of V_{g1} from a source electrode 402 to a drain electrode 403. A potential of -0.5 volts was applied to the drain electrode. The solid line shows the measurement curves determined at a voltage V_{g2} = -1 V. The dashed line shows the measurement curves determined at a voltage V_{g2} = +1 V. The current-voltage characteristic I_{d} — V_{g1} in FIG. 6a shows a counterclockwise hysteresis. This is typical for ferroelectric materials. Thus, a memory effect desired for a synapse is achieved by the ferroelectric material. By changing the voltage V_{g2,} the initial current is also influenced. This demonstrates the weight function of V_{g2} of a synapse.

The measurement curves shown in FIG. 6a were performed using the component shown in FIG. 6b. A thin p-doped silicon layer is separated from a Si substrate by an insulating layer. This is called silicon-on-insulator and abbreviated SOI. The insulating layer is formed by “buried silicon oxide”, which is also called BOX. The source electrode 402 and the drain electrode 403 formed by monocrystalline NiSi₂. The layers 402 and 403 are deposited on the thin p-doped silicon layer 401 by silicidation on very thin Ni. The layer 401 is 55 nm thick and is low p-doped. HfZrO was deposited as a ferroelectric layer 404 by atomic layer deposition (ALD). The thickness of the ferroelectric layer 404 may be 3 to 30 nm. The first electrode 405a and the second electrode 405b are produced from TiN. The first electrode 405a and the second electrode 405b serve as gate electrodes.

FIG. 7 shows an example of the measured synaptic characteristic of the element from FIG. 6 under the influence of a pulsed signal at the first gate, i.e. at the first gate electrode 405a. The current ID is plotted against the number of pulses PN. Thus, a voltage V_{g1} was applied to the first gate electrode in a pulsed manner. As indicated in FIG. 7, a long term potentiation (LTP) is generated by positive pulsed signals. A long-term depression (LTD) will be generated by negatively pulsed signals.

FIGS. 8a and 8b show several synapses with a crossbar structure. A cross-sectional view from A to A′ from FIG. 8a is shown in FIG. 8b. Two Schottky diodes of a synapse have a common semiconducting layer 501. A metal layer 502a of the first Schottky diode serves as a source electrode. A metal layer 502b serves as drain electrode. For producing, an electrically insulating layer 505 was first produced on the semiconducting layer in such a way that two accesses to the semiconducting layer remain. Subsequently, the two layers 502a and 502b were produced in such a way that they are electrically separated from each other. Then, the shown ferroelectric layers 502a and 502b with the gate electrodes 504a and 504b were produced. Advantageously, conventional producing techniques can be used to produce a plurality of synapses in the form of a crossbar structure in a technically simple manner.

FIG. 9 shows an example of a synapse comprising a first Schottky diode. The Schottky diode comprises a drain electrode 602 consisting of metal. The drain electrode 602 consisting of metal is applied on a semiconductor layer 601. The first Schottky diode can be modulated through a ferroelectric layer 604 with a gate electrode 605 according to the invention by means of a voltage V_{g}. A second Schottky diode with the semiconducting layer 601 and the drain electrode 603 consisting of metal may be present. This can be operated with a bias voltage V_{D} in the flow direction. However, the semiconducting layer 601 and the drain electrode 603 consisting of metal need not be selected such that a second Schottky diode is present. Instead, the semiconducting layer 601 and the drain electrode 603 consisting of metal may be a ohmic contact.

The first Schottky diode 602, 601 is operated under a reverse bias voltage. This synaptic element operates like a single gate transistor, which can be represented by the symbol of FIG. 9b.

FIG. 10 shows a synaptic element in a vertical arrangement. A layer 701 consisting of metal may serve as a substrate. However, the layer 701 consisting of metal can also be applied on a substrate. The layer 701 consisting of metal serves as a drain electrode. The layer 701 consisting of metal is therefore configured such that it can be connected to a voltage V_{D}. A semiconducting layer 702 is applied on the layer 701 consisting of metal. The layer 701 consisting of metal and the semiconducting layer 702 may be a Schottky diode. On the semiconducting layer an insulator layer 703a, 703b has been applied on in such a way that an access to the semiconducting layer 702 remains on the upper side. The access may also have been created subsequently after deposition of the insulating layer 703a, 703b, such as by etching. A metallic layer 704 was subsequently deposited on the upper side. This contacts the semiconducting layer 702 through the access. The metallic layer 704 serves as a source electrode. It can therefore be connected to a voltage Vs. The metallic layer 704 and the semiconducting layer 702 form a Schottky diode. A ferroelectric layer 705 was deposited on the metallic layer 704. A metallic layer 706 was deposited on the ferroelectric layer 705. The metallic layer 706 serves as a gate electrode. It can therefore be connected to a voltage V_{G}.

The structure shown in the FIG. 10 can be rotated by 180°. This structure shown in FIG. 10 is C2 rotation invariant.

FIGS. 11a and 11b symbolize a neural element with a synapse according to the invention, wherein a transistor and a resistor are present. The transistor may be either a dual-gate transistor 801 or a single-gate transistor 803. These transistors represent a synaptic element. The resistors 802 and 804 act as pull-up / pull-down resistors. By adjusting the conductance of the resistors, the activation of a neuron can be adjusted.

FIG. 12 illustrates a neural network with multiple synapses according to the invention and with conventional CMOS neurons. The synapses are shown in transistor representation Xi, Wi, ..., Xₙ, Wₙ on the left. A conventional neural element is shown on the right. The synapse can be a single-gate element as shown in FIG. 9 and FIG. 10. The producing of the synapses can be performed according to the CMOS neuron method to avoid the high-temperature treatment during the CMOS process. Synapses according to the invention may be combined with conventional neurons, which is illustrated by FIG. 12.

FIG. 13 sketches a synapse serving as a neuron-to-neuron connection. A signal 904 flows in one direction and that is from the presynaptic neuron 901 to the postsynaptic neuron 903. Also shown is a neuromodulator 902. The structure shown in FIG. 13 can be realized by the invention. The first gate (V_{g1}) of FIGS. 2 and 3, formed by 105a/205a, may serve as a presynaptic neuron. The source electrode serves as a postsynaptic neuron. The second gate (V_{g2}), formed by 105b/205b, serves as a neuromodulator. Thus, processing, learning and modulation functions can be realized simultaneously.

FIG. 14 illustrates how the component shown in FIG. 11a can be used as a two-input NAND gate.

FIG. 15 illustrates how a component according to FIG. 2b can be used as an AND gate, where Iₒᵤₜ is the current flowing out through D.

1. A synaptic component for a neural network, comprising:
a layer of a semiconductor;
a source electrode connected to the semiconducting layer; and
a drain electrode connected to the semiconducting layer, wherein the source electrode is spatially separated from the drain electrode, wherein the source electrode and the semiconducting layer form a first Schottky diode, and wherein the source electrode is separated from a first gate electrode by ferroelectric material.

2. The synaptic component according to claim 1, wherein the drain electrode forms with the semiconducting layer a second Schottky diode.

3. The synaptic component according to claim 1, wherein the drain electrode is separated from a second gate electrode by ferroelectric material, and wherein the first gate electrode is spatially separated from the second gate electrode.

4. The synaptic component according to claim 3, wherein the source electrode and the drain electrode are located on one side of the semiconducting layer and/or at opposite ends of the semiconducting layer.

5. The synaptic component according to claim 1, wherein the semiconducting layer is located above a substrate or in that the semiconducting layer is a substrate.

6. The synaptic component according to claim 1, wherein the semiconducting layer is a semiconductor heterostructure.

7. The synaptic component according to claim 1, wherein ferroelectric material is present as a layer which is at least partially located on the semiconducting layer.

8. The synaptic component according to claim 1, wherein ferroelectric material is present as a layer which is at least partially located on the source electrode and/or the drain electrode.

9. The synaptic component according to claim 8, wherein the ferroelectric material is present as a single layer which is located both at least partially on the source electrode and at least partially on the drain electrode.

10. The synaptic component according to claim 1, wherein ferroelectric material is present as a layer and the first gate electrode and/or the second gate electrode are located on one side of the ferroelectric layer and the source electrode and/or the drain electrode are located on the opposite side of the ferroelectric layer.

11. The synaptic component according to claim 1, wherein the component is electrically connected to at least one further component in series or in parallel to form a crossbar structure.

12. The synaptic component according to claim 1, wherein the ferroelectric material is selected from: doped HfO2 ferroelectric, a perovskite ferroelectric, an organic ferroelectric.

13. The synaptic component according to claim 1, wherein the metal for a Schottky diode is selected from: Al, Ag, Au, Cu, Cr, Mo, Ni, Nb, Pt, Ti, Ni, TiN, TaN, or a metal semiconductor alloy such as silicides, germanides, metal-SiGeSn alloys.

14. The synaptic component according to claim 1, wherein the semiconducting layer is partially covered with a layer of electrically insulating material.

15. A neural network, comprising:
the synaptic component according to claim 1; and
a neuron electrically connected to the synaptic component.

16. A method of operating a synaptic component according claim 1, wherein the first Schottky diode is connected in reverse direction and an electric voltage is applied to the first gate electrode in a pulsed manner.

17. The synaptic component according to claim 7, wherein the ferroelectric material is present as a single layer which is located both at least partially on the source electrode and at least partially on the drain electrode.
